(19) United States
(12) Patent Application Publication
(10) Pub. No.: US 2018/0254661 A1
(43) Pub. Date: Sep. 6, 2018

(54) INFORMATION OUTPUT APPARATUS, AND INFORMATION OUTPUT METHOD

(71) Applicant: NEC Corporation, Minato-ku, Tokyo (JP)

(72) Inventors: Takahiro TOIZUMI, Tokyo (JP); Ryota SUZUKI, Tokyo (JP); Eisuke SANEYOSHI, Tokyo (JP); Shigeru KOUMOTO, Tokyo (JP)

(73) Assignee: NEC Corporation, Minato-ku, Tokyo (JP)

(21) Appl. No.: 15/754,392

(22) PCT Filed: Aug. 4, 2016
(86) PCT No.: PCT/JP2016/072904

§ 371 Date: Feb. 22, 2018

(30) Foreign Application Priority Data
Sep. 3, 2015 (JP) 2015-173672

(51) Int. Cl. H02J 13/00; G01R 21/06; G06F 17/30; H04Q 9/00; G06F 3/0482

(52) U.S. Cl. CPC H02J 13/001; G01R 21/06; G06F 3/0482; H04Q 9/00; G06F 17/30548

(57) ABSTRACT

An object of the invention is to provide a new technique for displaying an operation state of an electric device. Provided is an information output apparatus including a unit that creates a group on the basis of attribute information related to plural electric devices and displays time-series data of current consumption or power consumption of the electric devices for each group.

### TECHNICAL FIELD

The present invention relates to an information output apparatus, an information output method, and a program.

### BACKGROUND ART

There have been attempts to recognize operation states (power supply state, power consumption, and the like) of plural electric devices. Effects such as energy saving are expected by a user's recognition of the operation state of the electric device.

Patent Document 1 discloses a technique for extracting a feature value from measurement data detected by a measurement sensor, which is installed in the vicinity of a feeder service entrance, and inferring an operation state of each of plural electric devices on the basis of the feature value.

Patent Document 2 discloses a technique for inferring power consumption of each of an air conditioning device group including an outdoor unit and plural indoor units, a lighting equipment group, and a personal computer (PC) group on the basis of operation conditions, and proportionately dividing power consumption measured by a wattmeter at a ratio of the power consumption of each device group which is inferred, to obtain and display the power consumption of each of the air conditioning device group, the lighting equipment group, and the PC group.

### RELATED DOCUMENT

### Patent Document

[Patent Document 1] Japanese Patent No. 3403368

[Patent Document 2] Japanese Laid-open Patent Publication No. 2014-120108

### SUMMARY OF THE INVENTION

### Technical Problem

The inventors have found the following new problem as a result of the examination of a technique for displaying an operation state of an electric device toward a user.

In Patent Documents 1 and 2, an operation state such as power consumption of each electric device or each electric device group is inferred and an inference result is displayed for each inferred unit (for each electric device or for each electric device group). A huge increase in the number of electric devices or electric device groups for which inference and the like are performed leads to a huge increase in the amount of information accordingly, and thus there is a problem in that the overall recognition is difficult. An object of the invention is to provide a new technique for solving the above-described problem.

### Solution to Problem

According to the invention, there is provided an information output apparatus including a unit that creates a group on the basis of attribute information related to a plurality of electric devices and displays time-series data of current consumption or power consumption of the electric devices for each group.

In addition, according to the invention, there is provided an information output apparatus including an input reception unit that receives an input of attribute information related to electric devices, and an output unit that displays time-series data of current consumption or power consumption of the electric devices, which are grouped on the basis of the attribute information, for each group.

In addition, according to the invention, there is provided an information output method performed by a computer, the method including causing a step of creating a group on the basis of attribute information related to a plurality of electric devices and displaying time-series data of current consumption or power consumption of the electric devices for each group.

In addition, according to the invention, there is provided a program causing a computer to function as a unit that creates a group on the basis of attribute information related to a plurality of electric devices and displays time-series data of current consumption or power consumption of the electric devices for each group.

In addition, according to the invention, there is provided an information output method performed by a computer, the method including an input reception step of receiving an input of attribute information related to electric devices, and an output step of displaying time-series data of current consumption or power consumption of the electric devices, which are grouped on the basis of the attribute information, for each group.

In addition, according to the invention, there is provided a program causing a computer to function as an input reception unit that receives an input of attribute information related to electric devices, and an output unit that displays time-series data of current consumption or power consumption of the electric devices, which are grouped on the basis of the attribute information, for each group.

### Advantageous Effects of Invention

According to the invention, a new technique for displaying an operation state of an electric device is realized.

### BRIEF DESCRIPTION OF THE DRAWINGS

The above-described objects, other objects, features and advantages will be further apparent from the preferred example embodiments described below, and the accompanying drawings as follows.

FIG. 1 is a conceptual diagram illustrating an example of a hardware configuration of an apparatus according to this example embodiment.

FIG. 2 illustrates an example of a functional block diagram of an information output apparatus according to this example embodiment.

FIG. 3 is a schematic diagram illustrating an example of time-series data for each device according to this example embodiment.

FIG. 4 is a schematic diagram illustrating an example of electric device attribute information according to this example embodiment.

FIG. 5 is a schematic diagram illustrating an example of information displayed by the information output apparatus according to this example embodiment.

FIG. 6 is a schematic diagram illustrating an example of information displayed by the information output apparatus according to this example embodiment.

FIG. 7 illustrates an example of a functional block diagram of the information output apparatus according to this example embodiment.

FIG. 8 illustrates an example of a functional block diagram of the information output apparatus according to this example embodiment.

FIG. 9 is a schematic diagram illustrating an example of information which is usable to obtain time-series data for each device according to this example embodiment.

FIG. 10 is a schematic diagram illustrating an example of information which is usable to obtain time-series data for each device according to this example embodiment.

FIG. 11 is a diagram illustrating an application example of the information output apparatus according to this example embodiment.

### DESCRIPTION OF EMBODIMENTS

First, an example of a hardware configuration of an apparatus (information output apparatus) according to this example embodiment will be described. Units included in the apparatus of this example embodiment are realized by any combination of hardware and software on the basis of a central processing unit (CPU), a memory, a program loaded into the memory, a storage unit (can also store not only a program which has been stored in advance from the stage of shipping out the apparatus but also a program which is downloaded from a storage medium such as a compact disc (CD), or a server or the like on the Internet) such as a hard disk which stores the program, and an interface for network connection of an arbitrary computer. In addition, those skilled in the art can understand that various modification examples can be made to the realization method and the apparatus.

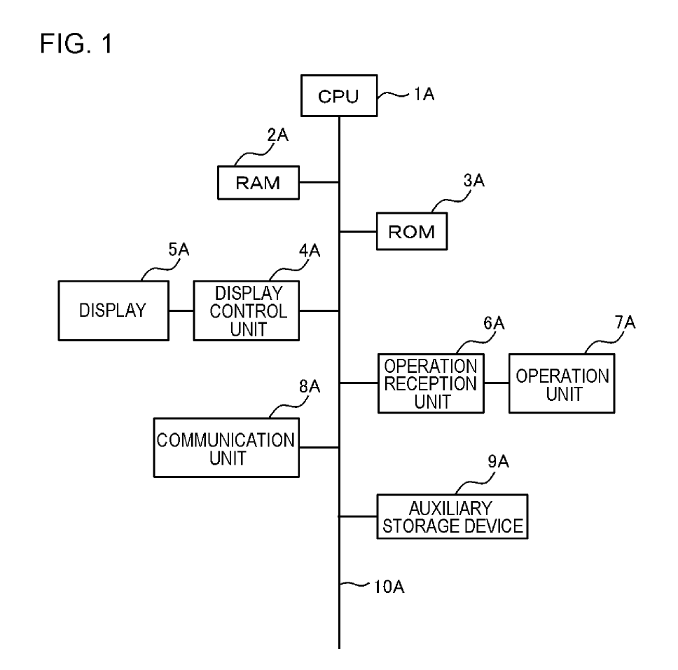

FIG. 1 is a conceptual diagram illustrating an example of a hardware configuration of an apparatus (information output apparatus) according to this example embodiment. As shown in the drawing, the apparatus according to this example embodiment includes, for example, a CPU 1A, a random access memory (RAM) 2A, a read only memory (ROM) 3A, a communication unit 8A, an auxiliary storage device 9A, and the like which are connected to each other by a bus 10A. Note that the apparatus according to this example embodiment may further include a display control unit 4A, a display 5A, an operation reception unit 6A, an operation unit 7A, and the like. Although not shown in the drawing, the apparatus according to this example embodiment may also include other components such as a microphone and a speaker. In addition, the apparatus may not include some of the components shown in the drawing.

The CPU 1A controls the overall computer of the apparatus together with the components. The ROM 3A includes an area in which programs for operating the computer, various application programs, various pieces of setting data used during the operation of the programs, and the like are stored. The RAM 2A includes an area, such as a work area for the operation of the programs, which transitorily stores data. The auxiliary storage device 9A is, for example, a hard disk drive (HDD), and can store large-capacity data.

The display 5A is, for example, a display device (a light emitting diode (LED) displayer, a liquid crystal display, an organic electro luminescence (EL) display, or the like). The display 5A may be a touch panel display integrated with a touch pad. The display control unit 4A reads data stored in a video RAM (VRAM), performs predetermined process on the read data, and transmits the processed data to the display 5A, thereby performing various screen displays. The operation reception unit 6A receives various operations through the operation unit 7A. The operation unit 7A includes an operation key, an operation button, a switch, a jog dial, a touch panel display, a keyboard, and the like. The communication unit 8A is connected to a network, such as the Internet or a local area network (LAN), in a wired and/or wireless manner to communicate with other electronic apparatuses. In addition, the communication unit 8A may be directly connected to another electronic device in a wired and/or wireless manner to communicate therewith.

Hereinafter, this example embodiment will be described. Note that functional block diagrams used in describing the following example embodiment show function-based blocks rather than hardware-based configurations. In the functional block diagrams, although a description is given such that each apparatus is implemented by one device, the implementation means therefor is not limited thereto. In other words, each apparatus may be configured to be physically or logically separated. Note that the same components will be denoted by the same reference numerals and signs, and a description thereof will not be repeated.

### First Example Embodiment

First, an outline of an information output apparatus according to this example embodiment will be described. When the information output apparatus acquires information (time-series data of current consumption or power consumption) which indicates an operation state of each of a plurality of electric devices, the information output apparatus totalizes the acquired information by using a predetermined method and outputs a totalization result.

Specifically, the information output apparatus collects electric devices to be monitored having a predetermined type of attribute information matching each other to create a group. The information output apparatus totalizes time-series data of current consumption or power consumption of electric devices, which belong to each group, for each group and outputs a totalization result.

In a case of this example embodiment, information indicating an operation state of each of a plurality of electric devices is not displayed as it is, and a totalization result obtained by totalizing the pieces of information for each group is displayed. Thus, it is possible to reduce the amount of information displayed.

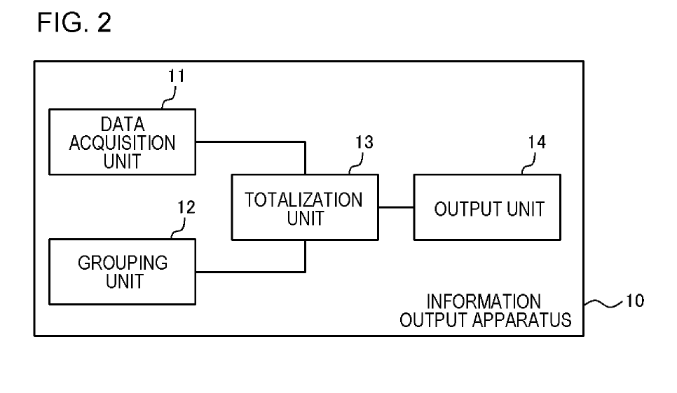

Next, a configuration of the information output apparatus according to this example embodiment will be described in detail. FIG. 2 illustrates an example of a functional block diagram of an information output apparatus 10 according to this example embodiment. As shown in the drawing, the information output apparatus 10 includes a data acquisition unit 11, a grouping unit 12, a totalization unit 13, and an output unit 14.

The data acquisition unit 11 acquires time-series data (hereinafter, may be referred to as “time-series data for each device”) of current consumption or power consumption of each of a plurality of electric devices.

A plurality of electric devices to be monitored are registered in the information output apparatus 10 in advance. The data acquisition unit 11 acquires time-series data for each device of each of the plurality of electric devices to be monitored.

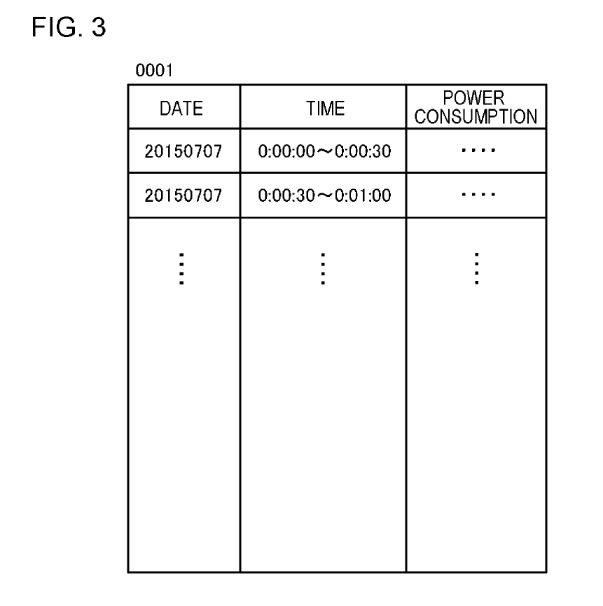

FIG. 3 schematically illustrates an example of time-series data for each device which is acquired by the data acquisition unit 11. The time-series data for each device which is shown in the drawing is time-series data of power consumption of an electric device specified by a serial number “0001”. The time-series data for each device indicates an integrated value (Wh) of power consumption for every 30 seconds from 0:00:00 on Jul. 7, 2015. Note that the time-series data for each device may be an integrated value for every minute, an integrated value for every 15 minutes, or an integrated value for every 30 minutes, or may be another integrated value.

The grouping unit 12 collects electric devices having a predetermined type of attribute information matching each other to create a group, on the basis of electric device attribute information in which one type or a plurality of types of attribute information are associated with each of the plurality of electric devices to be monitored.

The attribute information may include a device category (for example, an air conditioner, a television, a refrigerator, or the like) of each of the electric devices. The attribute information may also include at least one of a manager (for example, Mr./Ms. X, Mr./Ms. Y, “∘∘” department, “∘∘” section, father, mother, or the like), an installation area (for example, room 102 on the first floor, room 301 on the third floor, a bedroom, a living room, or the like), a manufacturer (for example, a company A, a company B, or the like), a price range (for example, 250,000 to 500,000 yen or 500,000 to 1,000,000 yen), an installation year (for example, 2015, 2014, or the like), a release year (for example, 2010, 2011, or the like), the model number of the device, the individual identification number of the device, rated power, an instantaneous waveform of power consumption, an instantaneous waveform of current consumption, time-series fluctuation data of a power value, and time-series fluctuation data of a current value. Note that this is just an example, and another attribute information may be included.

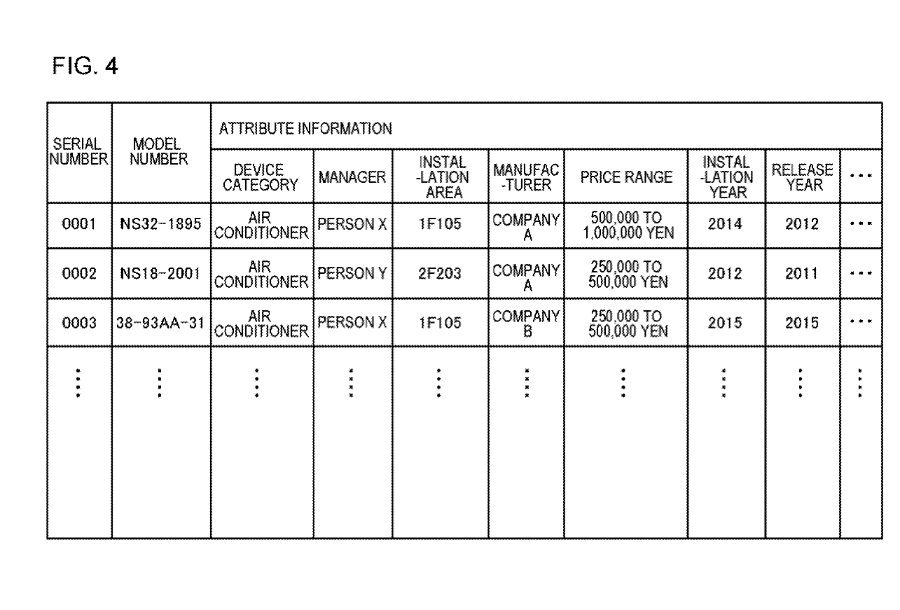

FIG. 4 schematically illustrates an example of electric device attribute information. In the example shown in the drawing, a serial number for identifying each electric device to be monitored, a model numbers of each electric device to be monitored, and attribute information are associated with each other. As the attribute information, a device category, a manager of each electric device, an installation area, a manufacturer, a price range, an installation year, and a release year are shown.

The grouping unit 12 may collect, for example, electric devices having device categories matching each other to create a group. In addition, the grouping unit 12 may collect electric devices having managers matching each other to create a group. In addition, the grouping unit 12 may collect electric devices having installation areas matching each other to create a group. In addition, the grouping unit 12 may collect electric devices having manufacturers matching each other to create a group.

In addition, the grouping unit 12 may collect electric devices having price ranges matching each other to create a group. In addition, the grouping unit 12 may collect electric devices having installation years matching each other to create a group. In addition, the grouping unit 12 may collect electric devices having release years matching each other to create a group.

Referring back to FIG. 2, for each group created by the grouping unit 12, the totalization unit 13 totalizes time-series data for each device of one or a plurality of electric devices, which belong to each group.

The totalization can be performed for each predetermined time slot. For example, a statistical value (for example, a total value, an average value, a maximum value, a minimum value, a frequent value, a median, or the like) of a value (for example, an integrated value of power consumption or current consumption) may be calculated for each predetermined time slot (for example, a time slot for every 30 seconds from 0:00:00 on Jul. 7, 2015). In this case, time-series data constituted by a statistical value for each predetermined time slot is obtained. Hereinafter, time-series data for each group after totalization may be referred to as “time-series data for each group”.

The output unit 14 displays a totalization result (time-series data for each group) of the totalization unit 13 for each group. The output unit 14 may display the respective totalization results of the plurality of groups at once, or may separately display the totalization results.

The output unit 14 may output the totalization results toward an external apparatus, and may display the totalization results on a display included in the external apparatus. In addition, the output unit 14 may display the totalization results on a display included in the information output apparatus 10 or a display connected to the information output apparatus 10.

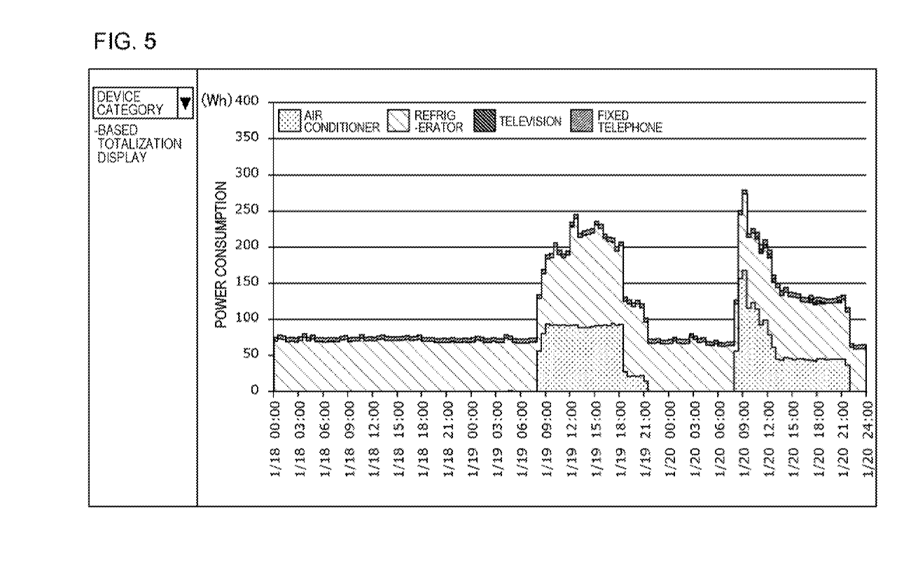

FIG. 5 schematically illustrates an example of the totalization results displayed by the output unit 14. In the example illustrated in FIG. 5, changes in power consumption with time are displayed in a stacked graph with a vertical axis representing power consumption and a horizontal axis representing a time.

In the example shown in the drawing, a plurality of electric devices are grouped on the basis of device categories (attribute information), and totalization results (time-series data of a total value) of a plurality of groups are displayed at once in the stacked graph.

According to the information output apparatus 10 of this example embodiment described above, instead of displaying acquired pieces of time-series data for each device (pieces of time-series data of current consumption or power consumption of each of the electric devices) as it is separately for each device, it is possible to group electric devices on the basis of a predetermined rule and display respective totalization results of the groups. As a result, the amount of information displayed is reduced, and a user easily recognizes a state.

Incidentally, as a method of displaying an operation state of the electric device, it is considered that when the operation state of the electric device is inferred or the like (the inference and measurement of power consumption or the like of each electric device are included), the result thereof is displayed as it is. That is, as in Patent Document 1 and 2, when an operation state such as power consumption of each electric device or each electric device group is inferred, an inference result is displayed for each unit inferred (for each electric device or for each electric device group).

In a case where the number of electric devices to be used, such as in one home, is limited, the above-described display method may be sufficient. However, when the number of electric devices for which inference and the like are performed, such as in the entire building, the entire apartment, or the entire community, is huge, the amount of information to be displayed is huge in a case of the above-described display method, and thus it is difficult to recognize the entire state.

In a case of the above-described display method, inference results of electric devices, even if they are the same type, are displayed as different electric devices due to model numbers or model years. Thus, the amount of information to be displayed is huge, making it difficult to recognize the entire state. That is, in a case where operation states (for example, changes in current consumption or power consumption with time) of a plurality of electric devices, of which the number is huge, are displayed at once in one time-series graph in an individually recognizable manner, the amount of information is increased, and thus it is difficult to recognize the entire state. Note that when the number of electric devices for which inference and the like are performed, such as not only in a home but also in the entire building, the entire apartment, or the entire community, is huge, the amount of information further is huge.

### Second Example Embodiment

In the first example embodiment, an example in which totalization results of a plurality of groups are displayed at once has been described with reference to FIG. 5. In this example embodiment, an example in which totalization results of a plurality of groups are individually displayed will be described.

It should be noted that, in this example embodiment, each of a plurality of groups (parent groups), which are created on the basis of a first type of attribute information, may be divided into a plurality of child groups on the basis of a second type of attribute information. Totalization results of a first parent group may be displayed separately for each child group.

An example of a functional block diagram of an information output apparatus 10 according to this example embodiment is illustrated in FIG. 2, similar to the first example embodiment. A configuration of a data acquisition unit 11 is the same as that in the first example embodiment.

A grouping unit 12 creates the plurality of parent groups on the basis of the first type of attribute information and thereafter creates the plurality of child groups for each parent group on the basis of the second type of attribute information. Other configurations of the grouping unit 12 are the same as those in the first example embodiment.

For example, the grouping unit 12 may create the plurality of parent groups separately for each device category (a first type of attribute information) and thereafter create the plurality of child groups separately for each manufacturer (a second type of attribute information). Note that a combination of the first type of attribute information and the second type of attribute information is not limited to that described here.

A totalization unit 13 totalizes time-series data for each child group. Other configurations of the totalization unit 13 are the same as those in the first example embodiment.

An output unit 14 displays a totalization result for each child group. Other configurations of the output unit 14 are the same as those in the first example embodiment.

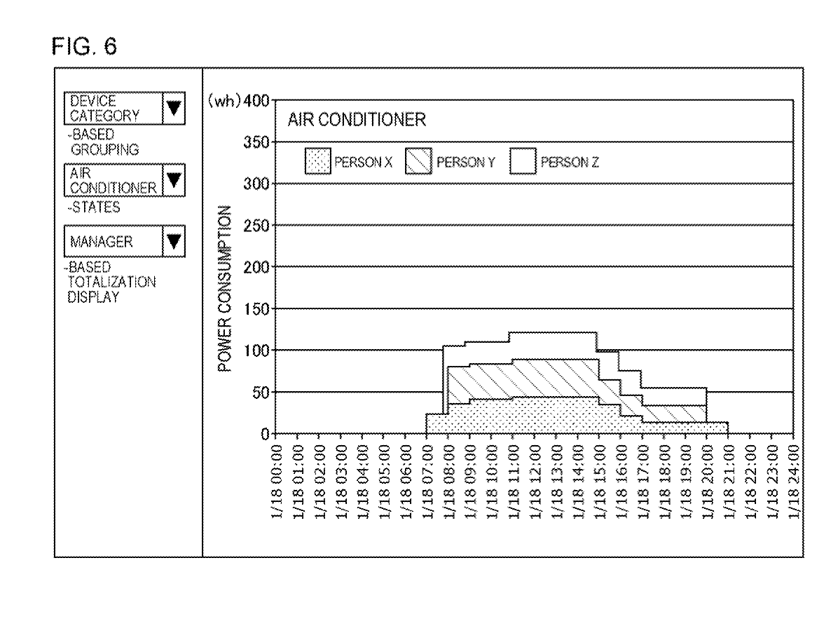

FIG. 6 schematically illustrates an example of totalization results displayed by the output unit 14. In the example illustrated in FIG. 6, changes in power consumption with time are displayed in a stacked graph with a vertical axis representing power consumption and a horizontal axis representing a time. Note that changes in power consumption of air conditioners with time are displayed separately for each manager.

That is, in a case of the example shown in the drawing, after a plurality of parent groups are created on the basis of a device category (first type of attribute information), a plurality of child groups are created on the basis of a manager (second type of attribute information) of each electric device. A totalization result (time-series data of a total value) is calculated for each child group, and the totalization results are shown in the stacked graph.

According to this example embodiment described above, it is possible to realize the same operations and effects as those in the first example embodiment.

In a case of this example embodiment, it is possible to divide a certain group (parent group) into child groups and to display a totalization result for each child group. According to this example embodiment, variations in a manner of showing information to be provided to a user increase. As a result, it is possible to provide an operation state of the electric device to be monitored in a mode which is truly desired by a user.

### Third Example Embodiment

This example embodiment is different from the first and second example embodiments in that a user can specify a totalization method. The other configurations are the same as those in the first and second example embodiments.

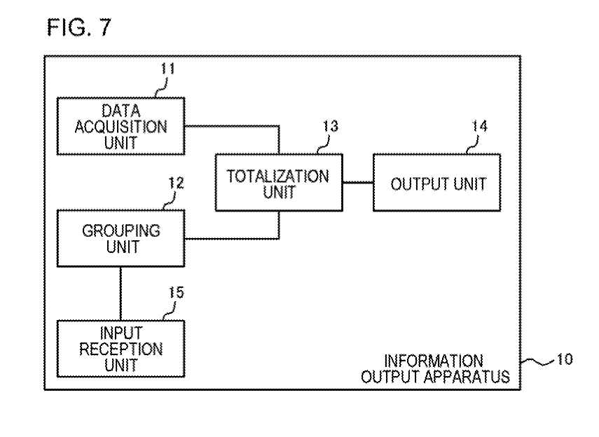

FIG. 7 illustrates an example of a functional block diagram of an information output apparatus 10 according to this example embodiment. As shown in the drawing, the information output apparatus 10 includes a data acquisition unit 11, a grouping unit 12, a totalization unit 13, an output unit 14, and an input reception unit 15. Configurations of the data acquisition unit 11, the totalization unit 13, and the output unit 14 are the same as those in the first and second example embodiments.

The input reception unit 15 receives a user's input for specifying a rule for grouping electric devices. The grouping unit 12 creates a group in accordance with the rule specified by the user's input.

For example, the input reception unit 15 may receive an input for specifying one type of attribute information. In this case, the grouping unit 12 collects electric devices having the specified type of pieces of attribute information matching each other to create a group.

In a case where the configuration in the second example embodiment is adopted, the input reception unit 15 may receive an input for specifying each of a first type of attribute information and a second type of attribute information. In this case, the grouping unit 12 collects electric devices having the pieces of a first type of attribute information matching each other to create a parent group, and collects electric devices having the pieces of a second type of attribute information matching each other to create a child group for each parent group. In the case of the example, the input reception unit 15 may further receive an input for specifying one parent group for which totalization results are displayed.

The input reception unit 15 may receive the above-described user's input through a graphical user interface (GUI) part such as a drop-down list or a radio button. FIGS. 5 and 6 illustrate an example of the input reception unit 15 that receives a user's input through a drop-down list.

According to this example embodiment described above, it is possible to realize the same operations and effects as those in the first and second example embodiments.

In a case of this example embodiment, a user can select a display style of an operation state of the electric device to be monitored. For example, in a case where the user desires to grasp changes in power consumption and the like with time for each device category, the user may specify grouping based on the device category. As a result, information as illustrated in FIG. 5 is displayed.

In a case where the user desires to grasp changes in power consumption of air conditioners with time separately for each manager, the user may specify a device category as a first type of attribute information, may specify a manager as a second type of attribute information, and may specify an air conditioner as a parent group to be displayed. As a result, information as illustrated in FIG. 6 is displayed.

In this manner, according to this example embodiment, it is possible to display an operation state of the electric device to be monitored in a user's desired mode.

### Fourth Example Embodiment

This example embodiment is different from the first to third example embodiments in that at least a portion of electric device attribute information of each electric device to be monitored is acquired from an external server. The other configurations are the same as those in the first to third example embodiments.

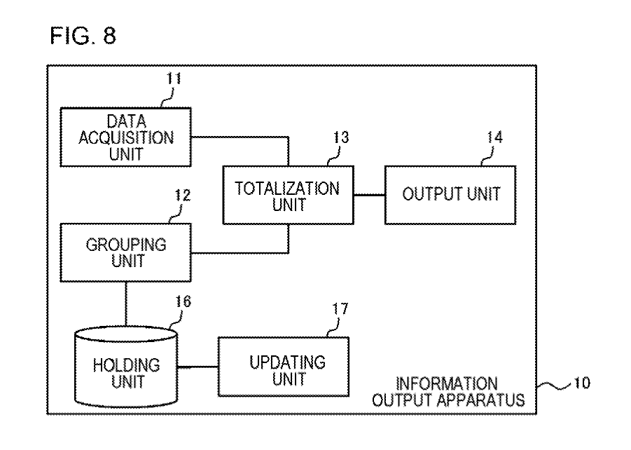

FIG. 8 illustrates an example of a functional block diagram of an information output apparatus 10 according to this example embodiment. As shown in the drawing, the information output apparatus 10 includes a data acquisition unit 11, a grouping unit 12, a totalization unit 13, an output unit 14, a holding unit 16, and an updating unit 17. Note that the information output apparatus 10 may further include an input reception unit 15.

Configurations of the data acquisition unit 11, the totalization unit 13, the output unit 14, and the input reception unit 15 are the same as those in the first to third example embodiments.

The holding unit 16 holds electric device attribute information of each electric device to be monitored. The grouping unit 12 groups the electric devices to be monitored on the basis of electric device attribute information held by the holding unit 16.

The updating unit 17 transmits identification information for identifying the electric device to be monitored to an external server, and acquires attribute information corresponding to the transmitted identification information from an external server. The updating unit 17 updates the electric device attribute information on the basis of the acquired attribute information.

As the identification information used in the processing, features such as an instantaneous waveform of power consumption, an instantaneous waveform of current consumption, time-series fluctuation data of a power value, and time-series fluctuation data of a current value may be used. The external server includes a database in which the identification information and the attribute information are associated with each other, and it is possible to associate the attribute information with the measured identification information by using the associations in the database. The updating unit 17 may acquire measurement data, such as an instantaneous waveform of power consumption, an instantaneous waveform of current consumption, time-series fluctuation data of a power value, and time-series fluctuation data of a current value, from a measurement sensor, and may transmit the acquired measurement data to the external server.

Another example of the identification information, a model number of the electric device is considered. The updating unit 17 may transmit the model number of the electric device to be monitored to the external server. The updating unit 17 may acquire at least one piece of attribute information, among a device category, a manufacturer, a price range, and a release year, from the external server. For example, a user may input the model number of the electric device to the information output apparatus 10. In addition, the updating unit 17 may hold correspondence information in which the features, such as an instantaneous waveform of power consumption, an instantaneous waveform of current consumption, time-series fluctuation data of a power value, and time-series fluctuation data of a current value, and the model number of the electric device are associated with each other. When the updating unit 17 acquires the measurement data, such as an instantaneous waveform of power consumption, an instantaneous waveform of current consumption, time-series fluctuation data of a power value, and time-series fluctuation data of a current value, from the measurement sensor, the updating unit may retrieve the correspondence information with the measurement data as a key to acquire a model number corresponding to the measurement data.

The external server may be configured to be accessible to the database in which at least one of the device category, the manufacturer, the price range, and the release year is associated with the model number of the electric device. When the external server receives a request for attribute information together with a model number, the external server may search the database to extract attribute information associated with a key (model number) and may return the extracted attribute information.

It should be noted that the updating unit 17 may be capable of receiving a user's input for specifying a portion of attribute information for each electric device to be monitored. For example, the updating unit 17 may receive the user's input for at least one piece of attribute information among a manager, an installation area, and an installation year. The updating unit 17 may update electric device attribute information on the basis of the user's input.

According to this example embodiment described above, the information output apparatus 10 can acquire attribute information of each electric device to be monitored from the external server. That is, it is possible to acquire attribute information, which is used to group the electric devices, from the external server. Thus, it is possible to reduce the burden on a user's work of inputting attribute information of each electric device to register.

### Fifth Example Embodiment

An information output apparatus 10 according to this example embodiment acquires time-series data for each device which is measured by a measurement unit to be described below. The measurement unit includes at least one of a first measurement unit and a second measurement unit. Note that the information output apparatus 10 may include or may not include the measurement unit.

The first measurement unit includes a plurality of measurement sensors each corresponding to an electric device to be monitored. Each of the plurality of measurement sensors is installed at a position where the current consumption or power consumption of each of the electric devices to be monitored can be measured. The first measurement unit can measure time-series data of current consumption or time-series data of power consumption (time-series data for each device) of each of the plurality of electric devices to be monitored, by using the plurality of measurement sensors. For example, the first measurement unit may acquire time-series data of current consumption or power consumption with a smart tap provided between each electric device and a plug receptacle.

The second measurement unit calculates results (time-series data for each device) of inference of current consumption or power consumption per unit time of each of the electric devices to be monitored, on the basis of the entire time-series data indicating the current consumption or power consumption of all of the plurality of electric devices to be monitored and training data in which a feature value of each operation state is associated with each of the plurality of operation states which can be assumed by the plurality of electric devices to be monitored.

The second measurement unit includes a measurement sensor. The measurement sensor is installed at a position where the current consumption or power consumption of all of the electric devices to be monitored can be measured. The measurement sensor may be installed, for example, in a distribution board. The second measurement unit acquires time-series measurement data (instantaneous waveform data: waveform data based on an AC frequency) which indicates the current consumption or power consumption of all of the electric devices to be monitored from the measurement sensor.

In addition, the second measurement unit includes a second computation unit that performs a predetermined computation process on the time-series measurement data. The second computation unit infers an operation state of each of the electric devices to be monitored on the basis of the time-series measurement data. The inference process may be performed by applying any related art (for example, means disclosed in Patent Document 1), but an example will be described below.

For example, the second computation unit extracts a predetermined feature value from instantaneous waveform data of a processing target with a predetermined time slot portion in the time-series measurement data as the processing target. The second computation unit extracts feature values from a plurality of processing targets in order by shifting a time slot which is set as a processing target.

There are various feature values extracted from the time-series measurement data, and examples of the feature values include a frequency intensity and a phase (harmonic component) of the current consumption, a phase, a change in current consumption, an average value, a peak value, an effective value, a wave height rate, a waveform rate, a convergence time of a change in current, an energization time, the position of a peak, a time difference between a peak position of a power supply voltage and a peak position of the current consumption, a power factor, and the like. Note that the invention is not limited thereto. The second computation unit may extract one type of feature value or may extract a plurality of types of feature values.

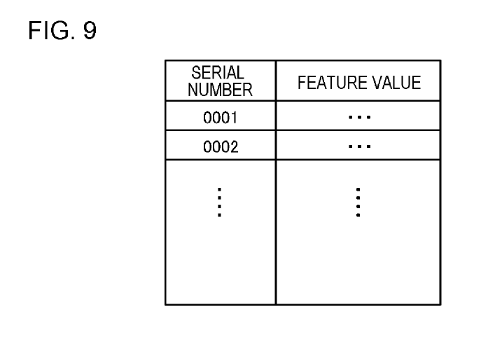

In addition, a feature value of each of the plurality of electric devices to be monitored is registered in the second computation unit as illustrated in FIG. 9. In FIG. 9, a serial number of each electric device to be monitored and a feature value are registered in association with each other. Note that a feature value may be registered for each power consumption or current consumption of the electric device.

The second computation unit obtains a feature value of each of a plurality of operation states which can be assumed by all of the electric devices to be monitored, on the basis of a feature value of each of the electric devices as illustrated in FIG. 9. The operation states which can be assumed by all of the electric devices to be monitored include, for example, “only a serial number 0001 is operating”, “a serial number 0001 and a serial number 0002 are operating”, and the like. Note that, in a case where a feature value for each power consumption or current consumption of each electric device to be monitored is registered, the operation states which can be assumed by all of the electric devices to be monitored include, for example, “a serial number 0001 is operating at ‘∘∘’W”, “a serial number 0001 is operating at ‘××’W”, “a serial number 0001 is operating at ‘∘∘’W, a serial number 0002 is operating at ‘ΔΔ’W, and a serial number 0003 is operating at ‘□□’W”, and the like. The respective feature values of the electric devices to be monitored as illustrated in FIG. 9 are added together, so that it is possible to obtain the feature value of each of the above-described operation states which can be assumed by all of the electric devices to be monitored.

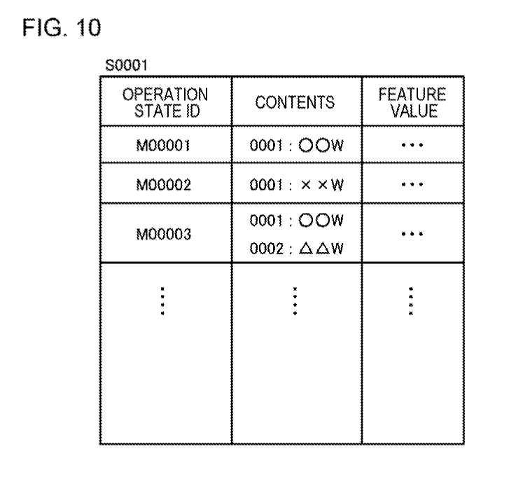

In this manner, as illustrated in FIG. 10, it is possible to obtain training data in which a feature value of each of operation states is associated with each of a plurality of operation states which can be assumed by all of the electric devices to be monitored. In FIG. 10, an operation state ID, contents (details of each operation state), and a feature value are associated with each other.

The second computation unit can obtain inference results (operation states of all of the electric devices to be monitored) by generating an inference model by machine learning using the training data and inputting a feature value extracted from the entire time-series measurement data to the generated inference model. The inference model can be configured to use, for example, multiple regression analysis, a neural network, a hidden Markov model, and the like.

An operation state (whether being in operation, power consumption, and the like) of the electric device in each time slot is inferred through the above-described inference process. As a result, time-series data for each device (see FIG. 3) is obtained for each electric device to be monitored.

Note that, as a modification example of the second measurement unit, a plurality of electric devices to be monitored may be divided into a plurality of groups, and results (time-series data for each device) of inference of the current consumption or power consumption per unit time of each of the electric devices to be monitored may be calculated for each group on the basis of the entire time-series data indicating current consumption or power consumption of all of the plurality of electric devices to be monitored belonging to each group and training data in which feature values of a plurality of operation states which can be assumed by the plurality of electric devices to be monitored are associated with the respective operation states. In this case, for example, a measurement sensor may be installed for each branch of a distribution board, may be installed for each plug receptacle, or the like.

According to this example embodiment described above, it is possible to realize the same operations and effects as those in the first to fourth example embodiments.

### Sixth Example Embodiment

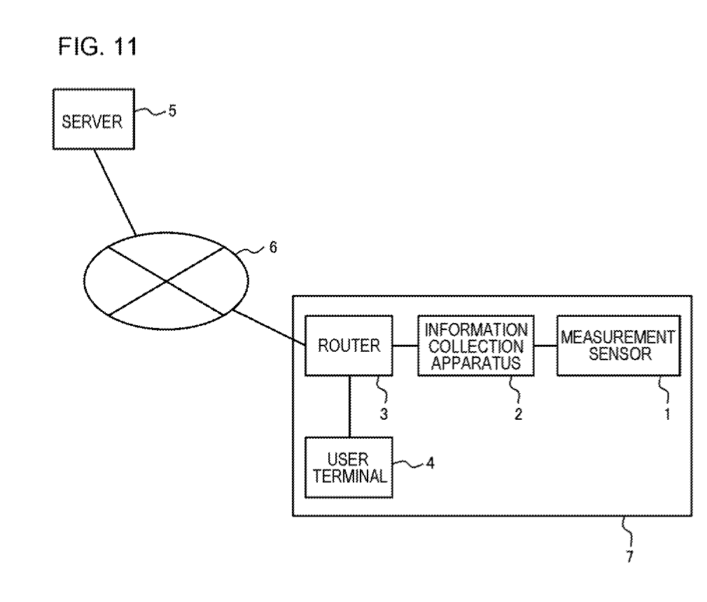

An application example of the information output apparatus 10 described in the first to fifth example embodiments will be described with reference to FIG. 11.

A power consumer 7 manages a measurement sensor 1, an information collection apparatus 2, a router 3, and a user terminal 4.

The measurement sensor 1 is one or a plurality of measurement sensors included in the measurement unit (first measurement unit, second measurement unit) described in the fifth example embodiment.

The information collection apparatus 2 acquires measurement data measured by the measurement sensor 1. The information collection apparatus 2 may include the first computation unit or the second computation unit described in the fifth example embodiment. Note that, instead of the information collection apparatus 2, a server 5 may include the first computation unit or the second computation unit described in the fifth example embodiment.

The information collection apparatus 2 transmits predetermined information to the server 5 through the router 3 and a network 6. For example, the information collection apparatus 2 may transmit the measurement data acquired from the measurement sensor 1 and data obtained through a computation process of the first computation unit or the second computation unit to the server 5.

The information output apparatus 10 according to this example embodiment is included in the information collection apparatus 2 or the server 5. A totalization result which is output by the output unit 14 of the information output apparatus 10 is output through a display of the information collection apparatus 2 or a user terminal 4.

According to this example embodiment described above, it is possible to realize the same operations and effects as those in the first to fifth example embodiments.

Hereinafter, an example of a reference configuration will be appended.

1. An information output apparatus including:

a unit that creates a group on the basis of attribute information related to a plurality of electric devices and displays time-series data of current consumption or power consumption of the electric devices for each group.

2. The information output apparatus according to 1, further including:

a data acquisition unit that acquires time-series data of current consumption or power consumption of each of the plurality of electric devices;

a grouping unit that creates a group of the electric devices on the basis of electric device attribute information in which one type or a plurality of types of attribute information are associated with each of the plurality of electric devices;

a totalization unit that totalizes the time-series data for each group; and

an output unit that displays a totalization result of the totalization unit for each group.

3. The information output apparatus according to 2,

wherein the grouping unit collects the electric devices having a predetermined type of attribute information matching each other to create a group, and

wherein the output unit displays the totalization results of a plurality of the groups at once.

4. The information output apparatus according to 2 or 3,

wherein the electric device attribute information includes a device category of each of the electric devices, as the attribute information.

5. The information output apparatus according to 4,

wherein the electric device attribute information further includes at least one of a manager, an installation area, a manufacturer, a price range, an installation year, a release year, a model number of the device, an individual identification number of the device, rated power, an instantaneous waveform of power consumption, an instantaneous waveform of current consumption, time-series fluctuation data of a power value, and time-series fluctuation data of a current value.

6. The information output apparatus according to any one of 2 to 5,

wherein the grouping unit creates a plurality of parent groups on the basis of a first type of attribute information, and thereafter creates a plurality of child groups for each parent group on the basis of a second type of attribute information,

wherein the totalization unit totalizes the time-series data for each child group, and

wherein the output unit displays the totalization result for each child group.

7. The information output apparatus according to any one of 2 to 6, further including: an input reception unit that receives a user's input for specifying a rule for grouping the electric devices,

wherein the grouping unit creates the group in accordance with the rule specified by the user's input.

8. The information output apparatus according to any one of 2 to 7,

wherein pieces of the time-series data of the plurality of electric devices are data measured using a plurality of sensors.

9. The information output apparatus according to any one of 2 to 8, further including:

a holding unit that holds the electric device attribute information; and

an updating unit that transmits identification information for identifying the electric device to an external server, and acquires the attribute information corresponding to the transmitted identification information from the external server to update the electric device attribute information on the basis of the acquired attribute information.

10. An information output apparatus including:

an input reception unit that receives an input of attribute information related to electric devices; and

an output unit that displays time-series data of current consumption or power consumption of the electric devices, which are grouped on the basis of the attribute information, for each group.

11. The information output apparatus according to 10,

wherein the input reception unit receives an input of second attribute information corresponding to a parent group created on the basis of the attribute information, and

wherein the output unit displays time-series data of current consumption or power consumption for each of a plurality of child groups grouped on the basis of the second attribute information.

12. An information output method performed by a computer, the method including:

creating a group on the basis of attribute information related to a plurality of electric devices and displaying time-series data of current consumption or power consumption of the electric devices for each group.

12-2. The information output method performed by the computer according to 12, further including:

a data acquisition step of acquiring time-series data of current consumption or power consumption of each of the plurality of electric devices,

a grouping step of creating a group of the electric devices on the basis of electric device attribute information in which one type or a plurality of types of attribute information are associated with each of the plurality of electric devices,

a totalization step of totalizing the time-series data for each group, and

an output step of displaying a totalization result, which is obtained by the totalization step, for each group.

12-3. The information output method according to 12-2,

wherein the grouping step includes collecting the electric devices having a predetermined type of attribute information matching each other to create a group, and

wherein the output step includes displaying the totalization results of a plurality of the groups at once.

12-4. The information output method according to 12-2 or 12-3,

wherein the electric device attribute information includes a device category of each of the electric devices, as the attribute information.

12-5. The information output method according to 12-4,

wherein the electric device attribute information further includes at least one of a manager, an installation area, a manufacturer, a price range, an installation year, a release year, a model number of the device, an individual identification number of the device, rated power, an instantaneous waveform of power consumption, an instantaneous waveform of current consumption, time-series fluctuation data of a power value, and time-series fluctuation data of a current value.

12-6. The information output method according to any one of 12-2 to 12-5,

wherein the grouping step includes creating a plurality of parent groups on the basis of a first type of attribute information, and thereafter creating a plurality of child groups for each parent group on the basis of a second type of attribute information,

wherein the totalization step includes totalizing the time-series data for each child group, and

wherein the output step includes displaying the totalization result for each child group.

12-7. The information output method performed by the computer according to any one of 12-2 to 12-6, further including:

an input reception step of receiving a user's input for specifying a rule for grouping the electric devices,

wherein the grouping step includes creating the group in accordance with the rule specified by the user's input.

12-8. The information output method according to any one of 12-2 to 12-7,

wherein pieces of the time-series data of the plurality of electric devices are data measured using a plurality of sensors.

12-9. The information output method performed by the computer according to any one of 12-2 to 12-8, further including:

holding the electric device attribute information; and

an updating step of transmitting identification information for identifying the electric device to an external server, and acquiring the attribute information corresponding to the transmitted identification information from the external server to update the electric device attribute information on the basis of the acquired attribute information.

13. A program causing a computer to function as:

a unit that creates a group on the basis of attribute information related to a plurality of electric devices and displays time-series data of current consumption or power consumption of the electric devices for each group.

13-2. The program according to 13, causing the computer to further function as:

a data acquisition unit that acquires time-series data of current consumption or power consumption of each of the plurality of electric devices;

a grouping unit that creates a group of the electric devices on the basis of electric device attribute information in which one type or a plurality of types of attribute information are associated with each of the plurality of electric devices;

a totalization unit that totalizes the time-series data for each group; and

an output unit that displays a totalization result of the totalization unit for each group.

13-3. The program according to 13-2,

wherein the grouping unit collects the electric devices having a predetermined type of attribute information matching each other to create a group, and

wherein the output unit displays the totalization results of a plurality of the groups at once.

13-4. The program according to 13-2 or 13-3,

wherein the electric device attribute information includes a device category of each of the electric devices, as the attribute information.

13-5. The program according to 13-4,

wherein the electric device attribute information further includes at least one of a manager, an installation area, a manufacturer, a price range, an installation year, a release year, a model number of the device, an individual identification number of the device, rated power, an instantaneous waveform of power consumption, an instantaneous waveform of current consumption, time-series fluctuation data of a power value, and time-series fluctuation data of a current value.

13-6. The program according to any one of 13-2 to 13-5,

wherein the grouping unit creates a plurality of parent groups on the basis of a first type of attribute information, and thereafter creates a plurality of child groups for each parent group on the basis of a second type of attribute information,

wherein the totalization unit totalizes the time-series data for each child group, and

wherein the output unit displays the totalization result for each child group.

13-7. The program according to any one of 13-2 to 13-6, causing the computer to further function as:

an input reception unit that receives a user's input for specifying a rule for grouping the electric devices,

wherein the grouping unit creates the group in accordance with the rule specified by the user's input.

13-8. The program according to any one of 13-2 to 13-7,

wherein pieces of the time-series data of the plurality of electric devices are data measured using a plurality of sensors.

13-9. The program according to any one of 13-2 to 13-8, causing the computer to further function as:

a holding unit that holds the electric device attribute information; and

an updating unit that transmits identification information for identifying the electric device to an external server, and acquires the attribute information corresponding to the transmitted identification information from the external server to update the electric device attribute information on the basis of the acquired attribute information.

14. An information output method performed by a computer, the method including:

an input reception step of receiving an input of attribute information related to electric devices; and

an output step of displaying time-series data of current consumption or power consumption of the electric devices, which are grouped on the basis of the attribute information, for each group.

14-2. The information output method according to 14,

wherein the input reception step includes receiving an input of second attribute information corresponding to a parent group created on the basis of the attribute information, and

wherein the output step includes displaying time-series data of current consumption or power consumption for each of a plurality of child groups grouped on the basis of the second attribute information.

15. A program causing a computer to function as:

an input reception unit that receives an input of attribute information related to electric devices; and

an output unit that displays time-series data of current consumption or power consumption of the electric devices, which are grouped on the basis of the attribute information, for each group.

15-2. The program according to 15,

wherein the input reception unit receives an input of second attribute information corresponding to a parent group created on the basis of the attribute information, and

wherein the output unit displays time-series data of current consumption or power consumption for each of a plurality of child groups grouped on the basis of the second attribute information.

The application is based on Japanese Patent Application No. 2015-173672 filed on Sep. 3, 2015, the content of which is incorporated herein by reference.

What is claimed is:

1. An information output apparatus comprising:
a unit that creates a group on the basis of attribute information related to a plurality of electric devices and displays time-series data of current consumption or power consumption of the electric devices for each group.

2. The information output apparatus according to claim 1, further comprising:
a data acquisition unit that acquires time-series data of current consumption or power consumption of each of the plurality of electric devices;
a grouping unit that creates a group of the electric devices on the basis of electric device attribute information in which one type or a plurality of types of attribute information are associated with each of the plurality of electric devices;
a totalization unit that totalizes the time-series data for each group; and
an output unit that displays a totalization result of the totalization unit for each group.

3. The information output apparatus according to claim 2,
wherein the grouping unit collects the electric devices having a predetermined type of attribute information matching each other to create a group, and
wherein the output unit displays the totalization results of a plurality of the groups at once.

4. The information output apparatus according to claim 2,
wherein the electric device attribute information includes a device category of each of the electric devices, as the attribute information.

5. The information output apparatus according to claim 4,
wherein the electric device attribute information further includes at least one of a manager, an installation area, a manufacturer, a price range, an installation year, a release year, a model number of the device, an individual identification number of the device, rated power, an instantaneous waveform of power consumption, an instantaneous waveform of current consumption, time-series fluctuation data of a power value, and time-series fluctuation data of a current value.

6. The information output apparatus according to claim 2,
wherein the grouping unit creates a plurality of parent groups on the basis of a first type of attribute information, and thereafter creates a plurality of child groups for each parent group on the basis of a second type of attribute information,
wherein the totalization unit totalizes the time-series data for each child group, and
wherein the output unit displays the totalization result for each child group.

7. The information output apparatus according to claim 2, further comprising:
an input reception unit that receives a user's input for specifying a rule for grouping the electric devices,
wherein the grouping unit creates the group in accordance with the rule specified by the user's input.

8. The information output apparatus according to claim 2,
wherein pieces of the time-series data of the plurality of electric devices are data measured using a plurality of sensors.

9. The information output apparatus according to claim 2, further comprising:
a holding unit that holds the electric device attribute information; and
an updating unit that transmits identification information for identifying the electric device to an external server, and acquires the attribute information corresponding to the transmitted identification information from the external server to update the electric device attribute information on the basis of the acquired attribute information.

10. An information output apparatus comprising:
an input reception unit that receives an input of attribute information related to electric devices; and
an output unit that displays time-series data of current consumption or power consumption of the electric devices, which are grouped on the basis of the attribute information, for each group.

11. The information output apparatus according to claim 10,
wherein the input reception unit receives an input of second attribute information corresponding to a parent group created on the basis of the attribute information, and
wherein the output unit displays time-series data of current consumption or power consumption for each of a plurality of child groups grouped on the basis of the second attribute information.

12. (canceled)

13. (canceled)

14. An information output method performed by a computer, the method comprising:
an input reception step of receiving an input of attribute information related to electric devices; and
an output step of displaying time-series data of current consumption or power consumption of the electric devices, which are grouped on the basis of the attribute information, for each group.

15. (canceled)
